(19) United States
(12) Patent Application Publication
(10) Pub. No.: US 2010/0195291 A1
(43) Pub. Date: Aug. 5, 2010

(54) ELECTRONIC CIRCUIT MODULE AND METHOD OF MANUFACTURING THE SAME

(75) Inventors: Akiya KIMURA, Kanagawa-ken (JP); Taizo Tomioka, Kanagawa-ken (JP); Takahiro Aizawa, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/695,536

(22) Filed: Jan. 28, 2010

(30) Foreign Application Priority Data
Jan. 30, 2009 (JP) 2009-019773

(51) Int. Cl. H05K 1/18; H05K 3/30

(52) U.S. Cl. 361/748; 29/832

(57) ABSTRACT

An electronic circuit module includes a plurality of electronic parts mounted on a substrate, the space separating the electronic parts being filled with thermosetting insulating resin, the insulating resin being covered by metal foil so as to expose the profiles and the heights of the electronic parts, the outer periphery of the metal foil being electrically connected to a grounding electrode arranged on the substrate by means of a conductive material.

### CROSS-REFERENCE TO RELATED APPLICATION

This application is based upon and claims the benefit of priority from the prior Japanese Patent Application No. 2009-019773 filed on Jan. 30, 2009, the entire contents of which are incorporated herein by reference.

### TECHNICAL FIELD

The present invention relates to an electronic circuit module. More particularly, it relates to an electronic circuit module having a specifically devised shield structure.

### BACKGROUND

Electronic appliances including mobile phones have become more and more sophisticated and downsized in recent years. Electronic circuit modules that are to be contained in electronic appliances and in which electronic parts are mounted are required to be downsized and low-profiled but operate faster. For fast operations of electronic circuit modules, the use of shields is important in order to prevent them from producing operation errors due to electromagnetic noises emitted from electronic parts.

As a general method for shielding electronic circuit modules, techniques of covering the CPU and other components of the module that can be noise sources with a metal case have been proposed. FIGS. 6A through 6C of the accompanying drawings schematically illustrate a shield structure using a metal case and some of the steps for assembling it. Referring to FIGS. 6A through 6C, a grounding electrode pad 12 and a pad 14 for receiving electronic parts are formed on one of the opposite surfaces of a substrate 2 along the outer periphery of the region to be shielded. Solder paste 13 is supplied onto the grounding electrode pad 12 and the pad 14 (see FIG. 6A). In this state, an electric part 15 and a metal frame 16 are mounded on the solder paste 13, all of which are then heated for soldering (see FIG. 6B). The metal frame 16 and a metal ceiling plate 18 are made to engage with each other by way of claws to shield the electronic circuit module 19 (see FIG. 6C).

However, such a shield structure for covering an electronic part with a metal case requires a thickness of about 0.2 mm in order to keep the profile of the metal ceiling plate and such a thickness makes further low-profiling difficult. Since the height of a metal ceiling plate is defined so as to be able to accommodate the highest one of the electronic parts, useless space is produced between the metal ceiling plate and the other electronic parts and hence the internal space of the electronic appliance cannot be effectively exploited. Additionally, since the metal frame and the metal ceiling plate are made to engage with each other by way of claws, the shielding performance is degraded when the contact at any of the engaging sites is not reliable. The amount of solder necessary for rigidly securing the electronic parts and the amount of solder necessary for rigidly holding the metal frame will show a significant difference when the electronic parts to be mounted on a module are further downsized. Then, a uniform solder supplying process may no longer be able to cope with such a situation.

In view of the above-described circumstances, techniques of shielding an electronic circuit module by means of an electromagnetic shielding film instead of a metal case have been proposed. Referring to FIG. 7, electronic parts 20 are covered by insulating resin 21 to a thickness of 50 to 100 μm by spray coating, further covered by a conductive layer 22 to a thickness of 50 to 100 μm by spray coating and connected to a grounding electrode 24 at an aperture 23 (see, for example, Jpn. Pat. Appln. Laid-Open Publication No. 11-150391).

Referring to FIG. 8, alternatively, an electronic part 29 mounted on a substrate 28 is covered by a 50 μm-thick shielding film 27 that is formed by a conductive layer 25 and an insulating layer 26 that has already been set and connected to a grounding electrode by thermo-compression-bonding the outer peripheral edge of the film by means of a thermo-compression bonding apparatus 30 (see, for example, Jpn. Pat. Appln. Laid-Open Publication No. 2003-209390).

With the technique of forming an insulating resin cover by spray coating, a BGA and a 0402 chip resistor show a height difference of about 0.8 mm. In other words, surface undulations may be produced depending on the electronic parts mounted on a wiring substrate. Then, for instance, it is difficult to form a film with a thickness of 50 to 100 μm. While a film cover can be formed with ease when the film thickness is large, such a large film thickness entails high material cost. Additionally, when a conductive adhesive agent that contains silver particles is adopted as conductive paint, the volume resistivity will be as high as about 4.5×10⁻⁵ to 5.0×10⁻⁴ cm if the adhesive agent is of a low resistivity type. In other words, a thick film is required if compared with, for example, copper (1.7×10⁻⁶ Ω·cm).

With the technique of shielding by using a shielding film, on the other hand, all the peripheral edge of the shielding film is subjected to thermo-compression bonding. In other words, a backup region needs to be provided on the substrate for the thermo-compression bonding to consequently produce a relatively large electronic circuit module. Besides, the bonding parts of the electronic parts need to be additionally reinforced typically by under film in order to protect them against external impacts. Then, the net result will be an increased number of manufacturing steps.

### SUMMARY

It is an object of the present invention to provide an electronic circuit module showing a low volume resistivity and having a low-profiled shield structure and a method of manufacturing such an electronic circuit module.

In an aspect of the present invention, there is provided an electronic circuit module having electronic parts mounted on a substrate, the space separating the electronic parts being filled with thermosetting insulating resin, the thermosetting insulating resin being covered with metal foil so as to expose the profiles and the heights of the electronic parts, the outer peripheral edge of the metal foil being electrically connected to a grounding electrode arranged on the substrate by means of a conductive material.

### BRIEF DESCRIPTION OF THE DRAWINGS

FIG. 1 is a schematic cross-sectional view of an electronic circuit module according to a first embodiment of the present invention.

FIG. 2 is a schematic plan view of the shield structure part of the electronic circuit module.

FIGS. 3A through 3D are a schematic illustration of steps of a method of manufacturing an electronic circuit module according to the first embodiment of the present invention.

FIG. 4 is a schematic cross-sectional view of an electronic circuit module according to a second embodiment of the present invention.

FIGS. 5A through 5D are a schematic illustration of steps of a method of manufacturing an electronic circuit module according to the second embodiment of the present invention.

FIGS. 6A through 6C are a schematic illustration of an electronic circuit module having a known shield structure.

FIG. 7 is a schematic illustration of an electronic circuit module having another known shield structure.

FIG. 8 is a schematic illustration of an electronic circuit module having still another known shield structure.

### DETAILED DESCRIPTION

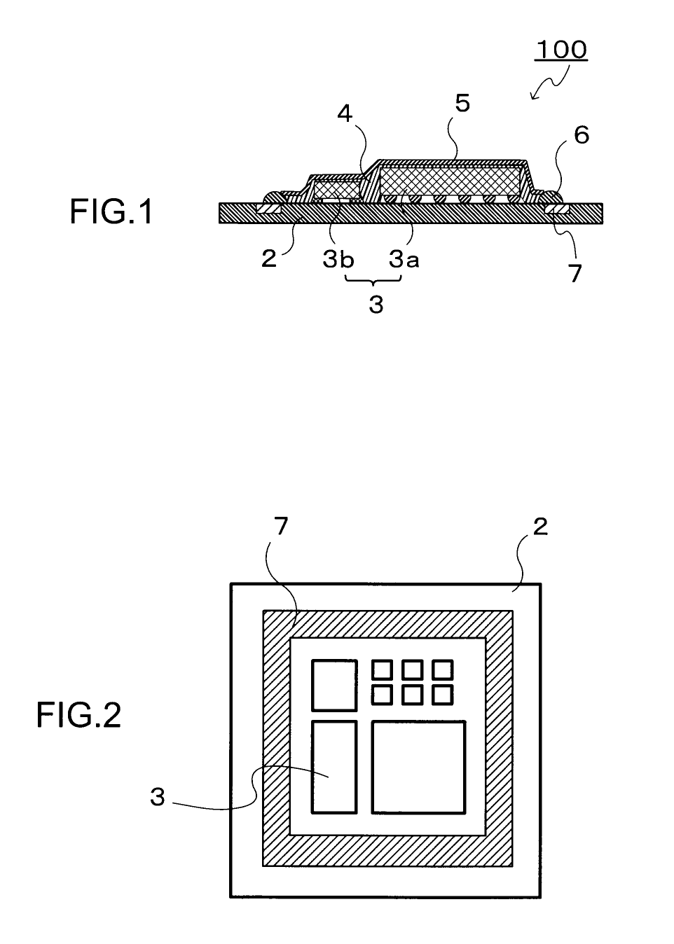

Now, preferred embodiments of the present invention will be described in greater detail by referring to the accompanying drawings. Throughout the drawings, same parts are denoted by same reference symbols and will not be described repeatedly. FIG. 1 is a schematic cross-sectional view of an electronic circuit module according to a first embodiment of the present invention. As shown in FIG. 1, a BGA 3a and a chip part 3b, which are electronic parts 3, are mounted on and fitted to a substrate 2 at predetermined respective positions. The space surrounding the BGA 3a and the chip part 3b including the top surfaces thereof is filled with insulating resin 4. Epoxy-based thermosetting resin may suitably be used for the insulating resin 4 because such resin shows a high degree of fluidity within its softening range where it is in a half-set state and hence flows into the gap between the BGA 3a and the chip part 3b so that no underfill is required to hold the electronic parts 3. Additionally, the electronic parts 3 are held rigidly once the insulating resin is set by heating. The outside of the insulating resin 4, or the side opposite to the side thereof where the insulating resin 4 is held in contact with the substrate 2 is covered by metal foil 5. In other words, the metal foil 5 covers the insulating resin 4 from the outside along the heights and the profiles of the electronic parts 3 and the like mounted on the substrate 2.

Since all the space surrounding the electronic parts 3, including the BGA 3a and the chip part 3b, is filled with insulating resin 4 in this embodiment, the metal foil 5 is not required to show a large thickness like that of a metal frame to maintain the profile of the module. In other words, the very thin metal foil 5 can provide a satisfactory shielding performance. A copper foil having a thickness between about 5 μm and 20 μm may suitably be used as the metal foil because it is hardly broken and can ensure a low profile for the electronic circuit module 100. When the metal foil 5 is copper foil, it may suitably be rolled copper foil because electrolytic copper foil can give off outgas although rolled copper foil is free from such a problem.

The metal foil 5 is by no means limited to rolled copper foil for this embodiment. Any metal foil showing a volume resistivity close to that of rolled copper foil may alternatively be used for this embodiment. Examples of metals that can be used as foil for this embodiment include beryllium, aluminum, chromium, iron, cobalt, nickel, zinc, niobium, molybdenum, technetium, ruthenium, rhodium, palladium, silver, cadmium, indium, tin, rhenium, osmium, iridium, platinum, gold, thallium, thorium, protactinium and alloys containing any of the above-listed metals.

Preferably, the insulating resin 4 and the metal foil 5 are tightly held in contact with each other over the entire surfaces of them in order to secure a satisfactory shielding effect by means of a very thin foil and realize a low profile for the entire module.

The outer peripheral edge of the metal foil 5 is electrically connected to a grounding electrode pad 7 of the substrate 2 by means of a conductive adhesive agent 6. The conductive adhesive agent 6 may be replaced by a solder material containing tin-silver-copper that operates also as conductive material. A film of gold, platinum, palladium, silver or an alloy containing any of them may be formed on the metal foil 5 at least in the region thereof to be connected to the conductive material.

FIG. 2 is a schematic plan view of the shield structure part of the electronic circuit module before the electronic parts 3 are mounted on the substrate 2 and covered by the insulating resin and the metal foil. The grounding electrode pad 7 is formed along the outer periphery of the region to be shielded. The grounding electrode pad 7 is typically formed by using 18 μm-thick copper foil whose surface is plated by nickel and gold to respective thicknesses of 3 μm and 0.1 μm. The width of the grounding electrode pad 7 is most suitably 1.0 mm from the viewpoint of downsizing the electronic circuit module.

Now, the method of manufacturing an electronic circuit module 100 having the above-described shield structure will be described below.

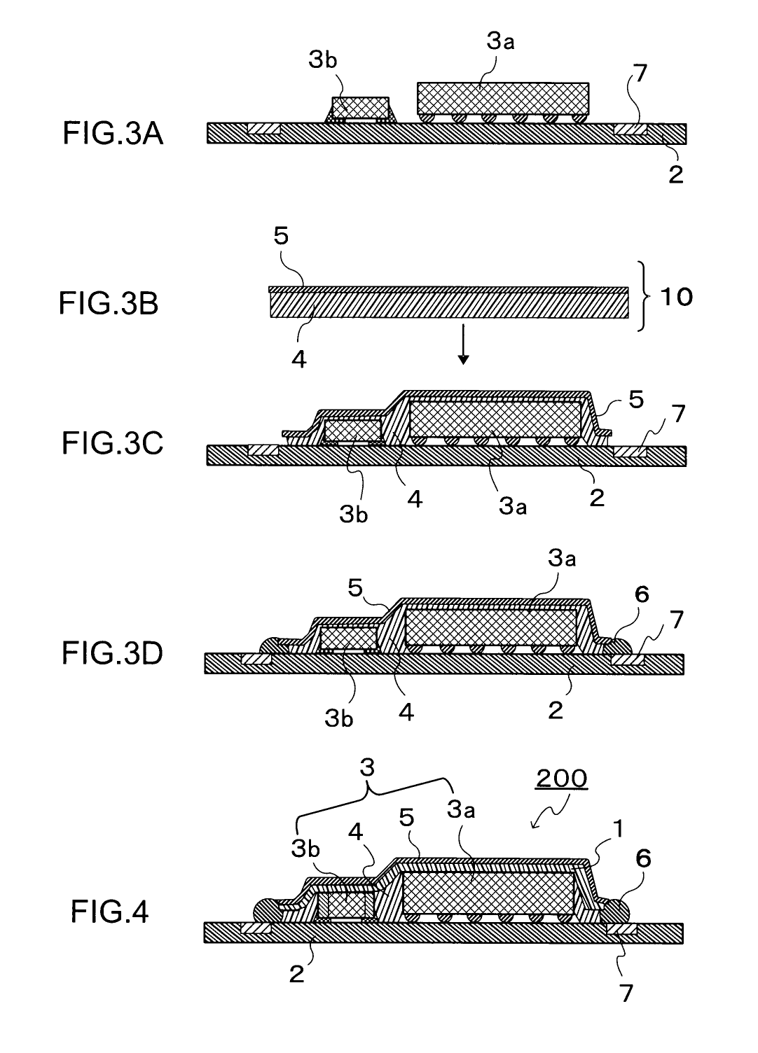

FIGS. 3A through 3D are a schematic illustration of steps of a method of manufacturing an electronic circuit module according to the first embodiment of the present invention. Firstly, electronic parts 3 are mounted on a circuit substrate 2 by means of a known surface mount technique (see FIG. 3A). Then, a shield sheet 10 is brought in (see FIG. 3B). The shield sheet 10 is prepared by bonding a resin sheet that is held in a half-set state within the softening range of the resin and a metal foil in advance. The shield sheet 10 may typically be formed by bonding a 100 μm-thick of insulating resin 4 and a 10 μm-thick shield layer 5 of metal foil. The insulating resin 4 is made of epoxy-based thermosetting resin that shows a high degree of fluidity until it is set by heat. The shield layer 5 is formed by rolled copper foil.

The shield sheet 10 is cut to show a contour that substantially hides the outer periphery of the grounding electrode pad 7. The shield sheet 10 is supplied to the top surfaces of the electronic parts 3 so as to be bonded to and cover the electronic parts 3 under pressure of about 1 MPa (see FIG. 3C). The insulating resin 4 softens as it is heated to a temperature level within its softening range and becomes fluidized under pressure so as to fill the space surrounding the electronic parts 3. Thereafter, the conductive adhesive agent 6 is applied to the substrate so as to connect to the shield layer 5 and the grounding electrode 7 as seen from the drawings. Subsequently, the insulating resin 4 and the conductive adhesive agent 6 of the shield sheet 10 are heated at 150° C. for 10 minutes (see FIG. 3D). The substrate 2 may also be heated in the heating operation. As a result of the heating, the insulating resin 4 is set to rigidly hold the electronic parts 3 on the substrate 2 and the shield layer 5 of the metal foil and the grounding electrode pad 7 are electrically connected to each other to form the shield structure.

When, for example, a conductive adhesive agent showing a volume resistivity of 4.5×10⁻⁵ Ω·cm is employed for the conductive layer, it requires a thickness of about 270 μm to provide an electric resistance equal to the 10 μm-thick copper foil. Thus, this embodiment can reduce the height of an electronic circuit module by about 260 μm from the conventional art.

As described above, if compared with the conventional art, this embodiment can realize a low profile electronic circuit module and makes it possible to perform an operation of filling insulating resin and that of forming a shield simultaneously to raise the manufacturing productivity.

Now, the second embodiment of the present invention will be described below. FIG. 4 is a schematic cross-sectional view of an electronic circuit module according to a second embodiment of the present invention. As shown in FIG. 4, a BGA 3a and a chip part 3b, which are electronic parts 3, are mounted on and fitted to a substrate 2 at predetermined respective positions. The space surrounding the BGA 3a and the chip part 3b is filled with first insulating resin 4. Epoxy-based thermosetting resin may suitably be used for the first insulating resin 4 because such resin shows a high degree of fluidity within its softening range where it is in a half-set state and hence flows into the gap between the BGA 3a and the chip part 3b so that no underfill is required to hold the electronic parts 3. Additionally, the electronic parts 3 are held rigidly once the insulating resin is set by heating. The entire top surface of the first insulating resin 4 is covered by second insulating resin 1. Thus, the second insulating resin 1 covers the insulating resin 4 from the outside along the heights and the profiles of the electronic parts 3 mounted on the substrate 2. Polyimide-based insulating resin may suitably be used for the second insulating resin 1 because it is highly flexible, soft and deformable. The second insulating resin 1 may suitably be about 50 μm thick.

The outside of the second insulating resin 1 is covered by metal foil 5. In other words, the metal foil 5 covers the second insulating resin 1 from the outside along the heights and the profiles of the electronic parts 3 and the like mounted on the substrate 2. Therefore, if the soft first insulating resin 4 flows excessively, the second insulating resin 1 that is interposed between the electronic parts 3 and the metal foil 5 prevents the electronic parts 3 and the metal foil 5 from immediately being brought into contact with each other for short-circuiting.

Since all the space surrounding the electronic parts 3, including the BGA 3a and the chip part 3b, the top surfaces thereof and the gap between them, is filled with the first insulating resin 4 and the top surface of the first insulating resin 4 is covered by the second insulating resin 1 in this embodiment, the shield layer 5 is not required to show a large thickness like that of a metal frame to maintain the profile of the module. In other words, the shield layer 5 that is formed by a very thin metal foil can provide a satisfactory shielding performance. A rolled copper foil having a thickness between about 5 μm and 20 μm may suitably be used as the shield layer 5 because it is hardly broken and can ensure a low profile for the electronic circuit module 200.

The outer peripheral edge of the shield layer 5 is electrically connected to a grounding electrode pad 7 of the substrate 2 by means of a conductive adhesive agent 6. The grounding electrode pad 7 is typically formed by using 18 μm-thick copper foil whose surface is plated by nickel and gold to respective thicknesses of 3 μm and 0.1 μm. The width of the grounding electrode pad 7 is most suitably 1.0 mm from the viewpoint of downsizing the electronic circuit module.

Now, the method of manufacturing an electronic circuit module 200 having the above-described shield structure will be described below.

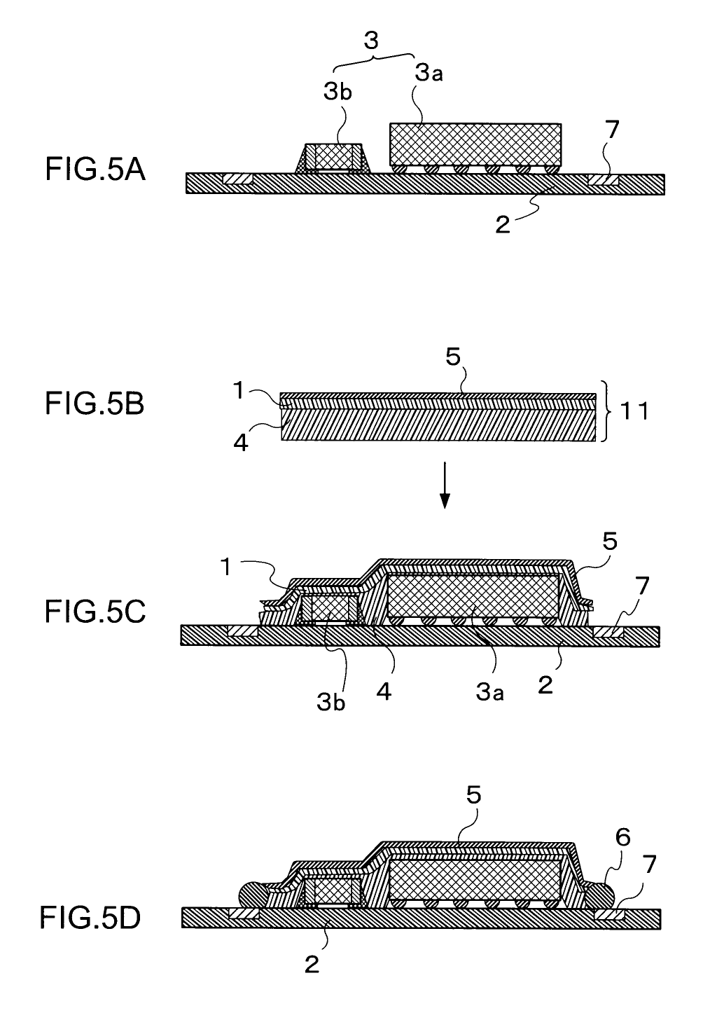

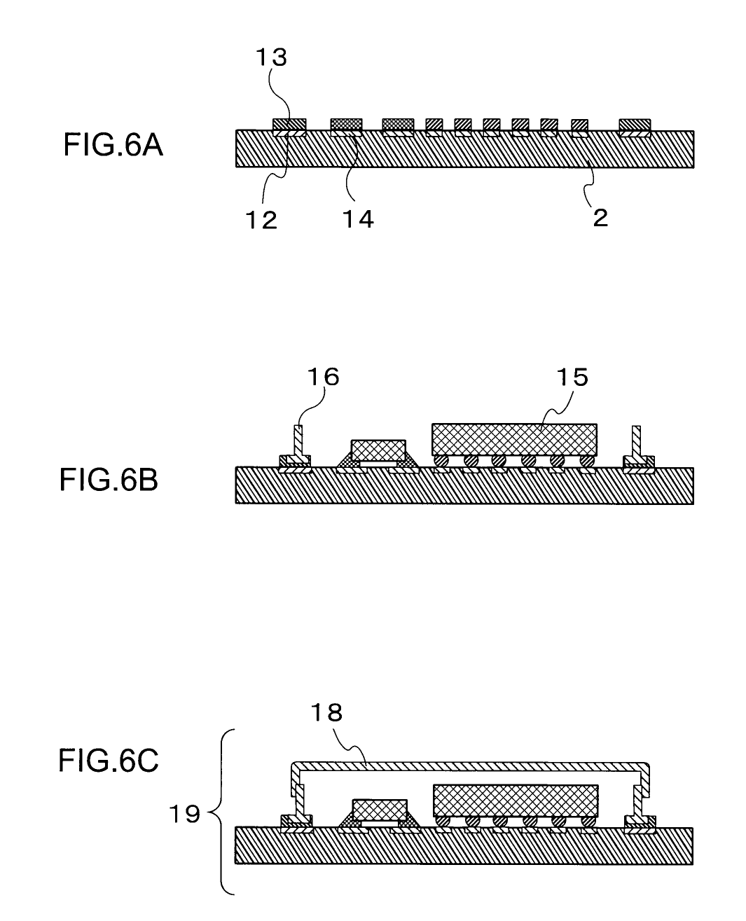

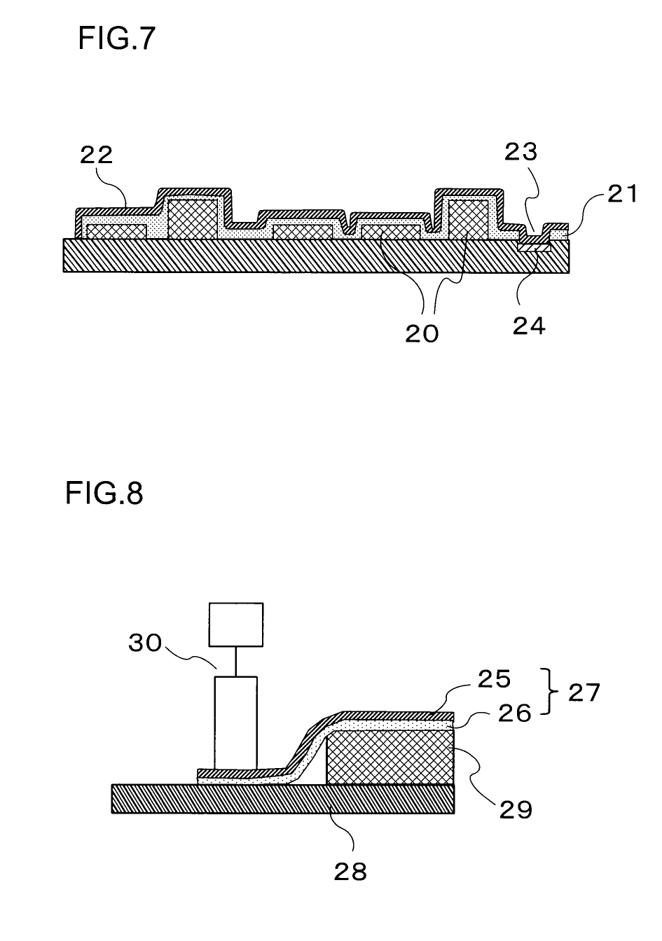

FIGS. 5A through 5D are a schematic illustration of the steps of a method of manufacturing an electronic circuit module according to the second embodiment of the present invention. Firstly, electronic parts 3 are mounted on a circuit substrate 2 by means of a known surface mount technique (see FIG. 5A). The electronic parts 3 typically include a BGA 3a and a chip part 3b.

Then, a shield sheet 11 is brought in (see FIG. 5B). The shield sheet 11 is prepared by bonding a sheet made of the first insulating resin, another sheet made of the second insulating resin and a rolled copper foil in advance. The shield sheet 11 may typically be formed by bonding a 50 μm-thick sheet of the first insulating resin 4, a 50 μm-thick sheet of the second insulating resin 1 and a 10 μm-thick shield layer 5 of metal foil. The first insulating resin sheet 4 is made of epoxy-based thermosetting resin that shows a high degree of fluidity until it is set by heat. The second insulating resin sheet 1 is made of soft polyimide-based insulating resin. The shield layer 5 is formed by metal foil, which is rolled copper foil.

The shield sheet 11 is cut to show a contour that substantially cover the outer periphery of the grounding electrode pad 7. The shield sheet 11 is supplied to the top surfaces of the electronic parts 3 so as to be bonded to and cover the electronic parts 3 under pressure of about 1 MPa (see FIG. 5C). As pressurized, the first insulating resin sheet 4 becomes softened and deformed to fill the space surrounding the electronic parts 3. When the shield sheet 11 is bonded, the region where the shield sheet 11 covers so as to be bonded is heated to about 80° C. in order to fill the gap between the BGA 3a and the chip part 3b and melt the first insulating resin sheet 4 that in a half-set state. As the first insulating resin sheet 4 is heated, its viscosity is lowered to 2.0×10⁴ Pa·s. Since the viscosity of the first insulating resin sheet 4 is low, it covers the electronic parts 3 and fills the gap between the electronic parts. Since the second insulating resin sheet 1 is held in tight contact with the rolled copper foil 5 over the substantially entire surface thereof, it prevents part electrodes (not shown) of the chip part 3b and the rolled copper foil 5 from contacting each other.

Thereafter, the conductive adhesive agent 6 is applied to the substrate so as to connect to the shield layer 5 of the metal foil and the grounding electrode pad 7.

Subsequently, the first insulating resin sheet 4 of the shield sheet 11 and the conductive adhesive agent 6 are heated at 150° C. for 10 minutes (see FIG. 5D). The substrate 2 may also be heated in the heating operation. As a result of the heating, the first insulating resin sheet 4 is set to rigidly hold the electronic parts 3 on the substrate 2 and the shield layer (the rolled copper foil) 5 and the grounding electrode pad 7 are electrically connected to each other to form the shield structure.

When, for example, a conductive adhesive agent showing a volume resistivity of 4.5×10⁻⁵ Ω·cm is employed for the conductive layer, it requires a thickness of about 270 μm to provide an electric resistance equal to a 10 μm-thick copper foil. Thus, this embodiment can reduce the height of an electronic circuit module by about 260 μm from the conventional art.

As described above, if compared with the conventional art, this embodiment can realize a low profile, prevent the metal foil and the electronic parts from short-circuiting and makes it possible to perform an operation of filling insulating resin and that of forming a shield simultaneously to raise the manufacturing productivity.

Note that, the present invention is not limited to the above-described embodiments, but may be modified into various forms in the implementation phase without departing from the gist of the invention by modifying the constituent elements. Moreover, the plural constituent elements disclosed in the above-described embodiments may be appropriately combined to form various aspects of the invention. For example, several constituent elements may be omitted from the entire constituent elements in the above-described embodiments. Furthermore, the constituent elements in the different embodiments may be appropriately combined.

What is claimed is:

1. An electronic circuit module comprising:
a plurality of electronic parts mounted on a substrate, the space separating the electronic parts being filled with thermosetting insulating resin, the insulating resin being covered by metal foil so as to expose the profiles and the heights of the electronic parts, the outer periphery of the metal foil being electrically connected to a grounding electrode arranged on the substrate by means of a conductive material.

2. The electronic circuit module according to claim 1, wherein
the metal foil is rolled copper foil.

3. The electronic circuit module according to claim 2, wherein
the rolled copper foil has a thickness between 5 μm and 20 μm.

4. The electronic circuit module according to claim 1, wherein
the insulating resin includes a first insulating resin layer made of epoxy-based thermosetting resin and a second insulating resin layer made of polyimide-based resin and the second insulating resin layer is tightly held in contact and covered by the metal foil.

5. The electronic circuit module according to claim 2, wherein
the insulating resin includes a first insulating resin layer made of epoxy-based thermosetting resin and a second insulating resin layer made of polyimide-based resin and the second insulating resin layer is tightly held in contact and covered by the metal foil.

6. The electronic circuit module according to claim 3, wherein
the insulating resin includes a first insulating resin layer made of epoxy-based thermosetting resin and a second insulating resin layer made of polyimide-based resin and the second insulating resin layer is tightly held in contact and covered by the metal foil.

7. A method of manufacturing an electronic circuit module comprising:
fitting electronic parts onto a substrate;
feeding a sheet formed by sequentially laying insulating resin held in a half-set state within the softening range thereof and metal foil and bringing the insulating resin into contact with the electronic parts;
pressurizing the sheet so as to lay the metal foil tightly on and expose the profiles and the heights of the electronic parts and make the insulating resin flow; and
heating the sheet to a temperature level not lower than the softening point of the insulating resin.

8. The method of manufacturing an electronic circuit module according to claim 7, wherein
the insulating resin is made of epoxy-based thermosetting resin and a second insulating resin layer made of second polyimide-based resin is interposed between the metal foil and the insulating resin.
